(19) United States
(12) Patent Application Publication
(10) Pub. No.: US 2025/0351669 A1
(43) Pub. Date: Nov. 13, 2025

(54) LIGHT-EMITTING ELEMENT AND DISPLAY DEVICE

(71) Applicant: Sharp Display Technology Corporation, Kameyama City, Mie (JP)

(72) Inventors: Yuki FUKUNARI, Sakai City, Osaka (JP); TAKAYUKI NAKA, Sakai City, Osaka (JP)

(21) Appl. No.: 18/868,885

(22) PCT Filed: Jul. 19, 2022
(86) PCT No.: PCT/JP2022/028002

§ 371 Date: Nov. 25, 2024

(51) Int. Cl. H10K 50/16; B82Y 20/00; B82Y 40/00; H10K 59/35; H10K 71/15; H10K 102/00

(52) U.S. Cl. CPC H10K 50/16; B82Y 20/00; H10K 59/352; B82Y 40/00; H10K 71/15; H10K 2102/331

(57) ABSTRACT

A light-emitting element includes: an anode; a cathode; a light-emitting layer between the anode and the cathode; and an electron transport layer as an intervening layer between the light-emitting layer and the cathode. The electron transport layer includes: at least one nanoparticle made of a first material containing a metal oxide; and a second material portion made of an inorganic, second material that has a lower electron transport ability than the first material and provided on at least a part of a surface of the at least one nanoparticle.

### TECHNICAL FIELD

The present disclosure relates to light-emitting elements and display devices including the light-emitting elements.

### BACKGROUND ART

Patent Literature 1 discloses increasing the bandgap of ZnO nanoparticles, thereby facilitating electron injection, by using, in an electron transport layer, nanoparticles of a Zn-containing metal oxide such as Zn₁₋ₓMgₓO (0<x≤0.5) prepared by making an alloy of ZnO nanoparticles with Mg. Patent Literature 1 further discloses that this configuration leads to provision of a light-emitting element that exhibits a higher luminous efficiency than a configuration in which ZnO nanoparticles are used in the electron transport layer.

### CITATION LIST

### Patent Literature

Patent Literature 1: Korean Patent Application Publication No. 1020160033520

### SUMMARY OF INVENTION

### Technical Problem

However, typical light-emitting elements including an inorganic material layer between the cathode and the light-emitting layer are excessively rich in electrons and have poor charge-carrier balance.

In addition, if the charge transport layer contains metal ions or a hydroxide, the carriers injected to this charge transport layer could be deactivated. Additionally, the metal ions or hydroxide could oxidize and hence deactivate the light-emitting material in the light-emitting layer.

For instance, there may be formed a single transport layer of a mixed compound of two materials that exhibit, for example, different carrier mobilities or two transport layers respectively containing such two materials. In such a case, problems will entail where the process of forming a transport layer of the two mixed materials may damage other layers or where the provision of the two transport layers may increase the thickness, and hence increase the drive voltage, of the light-emitting element.

### Solution to Problem

The present disclosure, in one aspect thereof, is directed to a light-emitting element including: an anode; a cathode; a light-emitting layer between the anode and the cathode; and an intervening layer between the light-emitting layer and the cathode, wherein the intervening layer includes: at least one nanoparticle made of a first material containing a metal oxide; and a second material portion made of an inorganic, second material that has a lower electron transport ability than the first material and provided on at least a part of a surface of the at least one nanoparticle.

The present disclosure, in another aspect thereof, is directed to a light-emitting element including: an anode; a cathode; a light-emitting layer between the anode and the cathode; and an intervening layer between the light-emitting layer and the cathode, wherein the intervening layer includes: at least one nanoparticle made of a first material containing at least one species selected from the group including zinc oxide, magnesium zinc oxide, lithium zinc oxide, titanium oxide, and strontium titanium oxide; and a second material portion made of a second material containing at least one species selected from the group including magnesium oxide, zirconium oxide, aluminum oxide, yttrium oxide, silicon oxide, zinc sulfide, magnesium zinc sulfide, and strontium sulfide and provided on at least a part of a surface of the at least one nanoparticle.

The present disclosure, in another aspect thereof, is directed to a light-emitting element including: an anode; a cathode; a light-emitting layer between the anode and the cathode; and an intervening layer between the light-emitting layer and the cathode, wherein the intervening layer is formed by a method involving: synthesizing a first solution containing at least one nanoparticle made of a first material; synthesizing a second solution prepared by adding, to the first solution, a second material that differs from the first material; forming a second material portion made of the second material on at least a part of a surface of the at least one nanoparticle by subjecting the second solution to sonication; and applying the second solution containing at least one of the at least one nanoparticle having the second material portion formed thereon.

The present disclosure, in another aspect thereof, is directed to a display device including: a substrate; and a red light-emitting element, a green light-emitting element, and a blue light-emitting element on the substrate, wherein at least one of the red light-emitting element, the green light-emitting element, and the blue light-emitting element is any of the light-emitting elements described above.

### Advantageous Effects of Invention

The present disclosure provides a light-emitting element and a light-emitting device both of which are capable of both lowering the drive voltage and improving the charge-carrier balance in the light-emitting layer while reducing damage to layers in manufacturing steps.

### BRIEF DESCRIPTION OF DRAWINGS

FIG. 1 is an aligned pair of a schematic cross-sectional view of a light-emitting element and a schematic cross-sectional view of a nanoparticle structural body in accordance with Embodiment 1.

FIG. 2 is a schematic energy band diagram of layers in the light-emitting element in accordance with Embodiment 1.

FIG. 3 is a flow chart representing an exemplary method of manufacturing a light-emitting element in accordance with Embodiment 1.

FIG. 4 is a graph representing exemplary X-ray diffraction spectra obtained by X-ray diffraction measurement on a first solution and a second solution in accordance with Embodiment 1.

FIG. 5 is a graph representing a relationship between application voltage and light-emission luminance for light-emitting elements in accordance with an example of the invention and a comparative example.

FIG. 6 is a graph representing a relationship between power consumption and light-emission luminance for light-emitting elements in accordance with an example of the invention and a comparative example.

FIG. 7 is an aligned pair of a schematic cross-sectional view of a light-emitting element and a schematic cross-sectional view of a nanoparticle structural body in accordance with Embodiment 2.

FIG. 8 is a schematic cross-sectional view of a light-emitting element in accordance with Embodiment 3.

FIG. 9 is a schematic cross-sectional view of a display device in accordance with Embodiment 4.

FIG. 10 is a schematic energy band diagram of layers in a red light-emitting element in accordance with Embodiment 4.

### DESCRIPTION OF EMBODIMENTS

### Embodiment 1

### Light-Emitting Element: Overview

The present embodiment describes, as an example, a light-emitting element of a charge injection type, in particular, a light-emitting element including quantum dots as a light-emitting material in the light-emitting layer. It should be understood however that the light-emitting element in accordance with the present embodiment is by no means limited to this example and may alternatively be, for example, an organic EL element (OLED element) containing an organic fluorescent material or an organic phosphorescent material in the light-emitting layer.

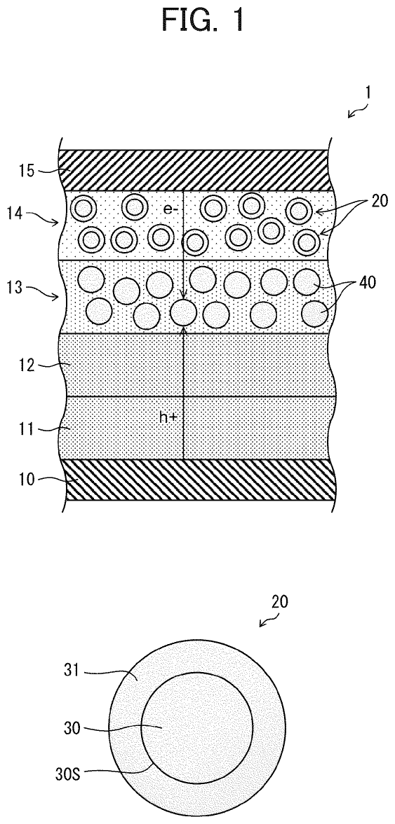

FIG. 1 is an aligned pair of a schematic cross-sectional view of a light-emitting element 1 and a schematic cross-sectional view of a nanoparticle structural body 20 (detailed later) in accordance with the present embodiment. Note that the schematic cross-sectional view of the light-emitting element 1 in FIG. 1 shows a cross-section of the light-emitting element 1 taken along the stack direction of layers in the light-emitting element 1 and that the schematic cross-sectional view of the nanoparticle structural body 20 in FIG. 1 shows a cross-section of the nanoparticle structural body 20 that passes through the center of a nanoparticle 30 (detailed later) in a schematic manner.

Referring to FIG. 1, the light-emitting element 1 includes an anode 10, a hole injection layer 11, a hole transport layer 12, a light-emitting layer 13, an electron transport layer 14, and a cathode 15, all of which are provided in this order when viewed from below. Note that the light-emitting element 1 is by no means limited to this example and may alternatively include these layers in reverse order, specifically, in the order of the cathode 15, the electron transport layer 14, the light-emitting layer 13, the hole transport layer 12, the hole injection layer 11, and the anode 10 when viewed from below.

### Light-Emitting Element: Anode and Cathode

The anode 10 and the cathode 15 are electrodes containing a conductive material and are electrically connected respectively to the hole injection layer 11 and the electron transport layer 14. When a voltage is applied to either one or both of the anode 10 and the cathode 15, holes h⁺ and electrons e⁻ are injected from the anode 10 and the cathode 15 to the hole injection layer 11 and the electron transport layer 14 respectively.

Either one or both of the anode 10 and the cathode 15 is/are a transparent electrode that is transmissive to visible light. The transparent electrode may be, for example, ITO (indium tin oxide), IZO (indium zinc oxide), SnO₂, or FTO (fluorine-doped tin oxide). In addition, either one of the anode 10 and the cathode 15 may be a reflective electrode. The reflective electrode may contain a metal material with a high visible light reflectance, and this metal material may be, for example, elemental Al, Ag, Cu, or Au or an alloy of these elements.

When the light-emitting element 1 has a top-emission structure in which light is taken out from the light-emitting layer 13 (detailed later) through the cathode 15, the anode 10 may be a reflective electrode, and the cathode 15 may be a transparent electrode. On the other hand, when the light-emitting element 1 has a bottom-emission structure in which light is taken out from the light-emitting layer 13 through the anode 10, the anode 10 may be a transparent electrode, and the cathode 15 may be a reflective electrode.

### Light-Emitting Element: Hole Injection Layer and Hole Transport Layer

The hole injection layer 11 transports the holes injected from the anode 10 to the hole transport layer 12. The hole transport layer 12 transports the holes injected from the hole injection layer 11 to the light-emitting layer 13. The hole injection layer 11 and the hole transport layer 12 may be made of an organic or inorganic hole-transportable material conventionally used in, for example, quantum dot-containing light-emitting elements or organic EL light-emitting elements.

In particular, the hole injection layer 11 contains an inorganic material, and the hole transport layer 12 contains an organic material, in the present embodiment. The inorganic material for the hole injection layer 11 may be, for example, MoO₃, NiO, or MgNiO. In addition, the organic material for the hole transport layer 12 may be, for example, 4,4′,4″-tris(9-carbazoyl)triphenylamine (TCTA), 4,4′-bis [N-(1-naphthyl)-N-phenyl-amino]-biphenyl (NPB), zinc phthalocyanine (ZnPC), di [4-(N,N-ditolylamino)phenyl]cyclohexane (TAPC), 4,4′-bis(carbazol-9-yl)biphenyl (CBP), 2,3,6,7,10,11-hexacyano-1,4,5,8,9,12-hexaazatriphenylene (HATCN), poly(N-vinylcarbazole) (PVK), poly(2,7-(9,9-di-n-octylfluorene)-(1,4-phenylene-((4-sec-butylphenyl)imino)-1,4-phenylene (TFB), or N,N′-bis(4-butylphenyl)-N,N′-bis(phenyl)-benzidine (Poly-TPD).

Note that throughout the present disclosure, the terms, “organic” and “organic material,” refer to substances with atomic bonds primarily made up of carbon atoms and also that the terms, “inorganic” and “inorganic material,” refer to non-organic substances. Therefore, it is desirable to consider throughout the present disclosure that the terms, “inorganic” and “inorganic material,” refer to substances with atomic bonds containing no carbon atoms. The terms, “inorganic” and “inorganic material,” may alternatively refer to substances with atomic bonds primarily containing no carbon atoms. In addition, the terms, “inorganic” and “inorganic material,” may be considered referring to substances with no carbon chains.

Among hole-transportable materials, organic materials generally have higher hole transportability than inorganic materials. On the other hand, among hole-transportable materials, inorganic materials generally have, for example, higher tolerance against foreign objects such as moisture and higher thermal resistance and are hence more reliable than organic materials. Therefore, the light-emitting element 1 exhibits improved reliability while exhibiting increased hole transport efficiency and improved luminous efficiency, owing to the provision of the hole injection layer 11 containing an inorganic material and the provision of the hole transport layer 12 containing an organic material.

It should be understood however that the hole injection layer 11 may contain a composite of PEDOT (poly(3,4-ethylenedioxythiophene)) and PSS (poly(4-styrene sulfonate)) called “PEDOT:PSS” or an organic material such as HATCN mentioned as an example above. In addition, the hole transport layer 12 may contain either a metal oxide such as NiO, MgNiO, LaNiO₃, CuO, Cu₂O, or MoO₃ or an inorganic material, for example, a material, such as CuSCN, prepared by bonding a CN group, a SCN group, or a SeCN group to a metal.

If either the hole injection layer 11 or the hole transport layer 12 contains an inorganic material, the hole injection layer 11 or the hole transport layer 12 may include a SAM (self-assembled monolayer) film at its interface with another layer. When this is the case, the hole injection layer 11 or the hole transport layer 12 can efficiently transport holes via the SAM film, thereby lowering the drive voltage of the light-emitting element 1.

### Light-Emitting Element: Electron Transport Layer

The electron transport layer 14 transports the electrons injected from the cathode 15 to the light-emitting layer 13. In the present embodiment, the electron transport layer 14 is an intervening layer containing an electron-transportable inorganic material and in particular contains the nanoparticle structural bodies 20 containing an inorganic material. The layer between the light-emitting layer 13 and the cathode 15 is referred to as an intervening layer throughout the present disclosure. Note that the following description will discuss an electron transport layer as an example of the intervening layer, which by no means limits the present disclosure. Alternatively, for example, the light-emitting element may include an electron injection layer and an electron transport layer as an intervening layer and may include an electron injection layer as the intervening layer in accordance with the present disclosure.

Referring to the schematic cross-sectional view of the nanoparticle structural body 20 in FIG. 1, a detailed description is now given of the nanoparticle structural bodies 20 in the electron transport layer 14. The nanoparticle structural body 20 includes: at least one nanoparticle 30 (first material portion, first portion) containing a first material (detailed later); and a second material portion 31 (second portion) containing a second material (detailed later) and provided on at least a part of a surface 30S of the nanoparticle 30.

In the present disclosure, the term, “nanoparticle,” refers to a dot (particle) composed of a particle with a maximum width of less than 1,000 nm. The nanoparticle may have any shape so long as the shape satisfies this maximum width and does not necessarily have a spherical three-dimensional shape (with a circular cross-sectional shape). The nanoparticle may have, for example, a polygonal cross-sectional shape, a virgulate three-dimensional shape, a ramal three-dimensional shape, a three-dimensional shape with an irregular surface, or a combination of any of these shapes.

Note that the electron transport layer 14 may further include an organic ligand coordinated to the outermost circumferential surface of the nanoparticle structural body 20. In addition, the electron transport layer 14 may further include an organic material such as a dispersant and/or a thickening agent to improve, for example, the dispersibility and film-forming property of the nanoparticles 30. Examples of such an organic material include oleic acid, oleyl amine, and 2-aminoethanol.

The first material includes an electron-transportable metal oxide and specifically contains at least one species selected from the group including zinc oxide, magnesium zinc oxide, lithium zinc oxide, titanium oxide, and strontium titanium oxide. Zinc oxide includes, for example, ZnO. Magnesium zinc oxide includes, for example, MgZnO. Lithium zinc oxide includes, for example, LiZnO. Titanium oxide includes, for example, TiO₂. Strontium titanium oxide includes, for example, SrTiO₃ (strontium titanate).

The second material is an inorganic material with lower electron transport ability than the first material. Throughout the present embodiment, the term, “electron transport ability,” refers to an ability to transport the electrons injected from other layers. For example, the second material has lower electron mobility than the first material, in other words, has lower ability to transport the electrons injected from other layers.

Specifically, the second material includes at least one species selected from the group including magnesium oxide, zirconium oxide, aluminum oxide, yttrium oxide, silicon oxide, zinc sulfide, magnesium zinc sulfide, and strontium sulfide. Magnesium oxide includes, for example, MgO. Zirconium oxide includes, for example, ZrO₂ (zirconia). Aluminum oxide includes, for example, Al₂O₃ (alumina). Yttrium oxide includes, for example, Y₂O₃. Silicon oxide includes, for example, SiO₂ (silica) or SiO (silicon monoxide). Zinc sulfide includes, for example, ZnS. Magnesium zinc sulfide includes, for example, MgZnS. Strontium sulfide includes, for example, SrS. Note that the compositions found in the chemical formulae in the present disclosure are desirably stoichiometric. It should be understood however that the present disclosure does not exclude non-stoichiometric compositions.

The structure of the electron transport layer 14 can be analyzed by, for example, cutting the electron transport layer 14 in the stack direction of the light-emitting element 1 to obtain a thin piece thereof and observing the thin piece under, for example, a TEM (transmission electron microscope). In particular, element analysis can be performed on the electron transport layer 14 by subjecting the thin piece to, for example, EDX (energy dispersive X-ray spectroscopy) or EELS (electron energy-loss spectroscopy). EELS is used if EDX is not feasible in the measurement.

For instance, if in the above-described EDX or EELS on the thin piece, a spectrum that has a peak unique to the first material or the second material is obtained from a particular position, it may be determined that there is a member containing the first material or the second material at that position. It is hence assumed, for example, that it has been confirmed that in the thin piece, at least a part of the member containing the second material is formed on the outer circumference of a member containing the first material. In such a case, it would be safe to judge that the electron transport layer 14 contains the nanoparticle structural body 20 including: the nanoparticle 30 containing the first material; and the second material portion 31 formed on the surface 30S of this nanoparticle 30. Note that the term, “the outer circumference of a member” here refers to a space up to 2 nm from the edge of the member. In other words, to confirm that the nanoparticle structural body 20 includes: the nanoparticle 30 containing the first material; and the second material portion 31 formed on at least a part of the surface 30S of the nanoparticle 30, one needs only to confirm that at least a part of the member containing the second material is formed in a space up to 2 nm from at least a part of the edge of the member containing the first material.

The thickness of the second material portion 31, in other words, the thickness from the surface 30S of the nanoparticle 30 to the outermost circumference of the nanoparticle structural body 20 may be from 0.4 nm to 2.0 nm, both inclusive, or from 0.4 nm to 1.0 nm, both inclusive. If the second material portion 31 has a thickness of greater than or equal to 0.4 nm, the second material portion 31 can be more reliably provided on the surface 30S of the nanoparticle 30 by the method detailed later. Meanwhile, if the second material portion 31 has a thickness of less than or equal to 2.0 nm, carriers can move by tunnel conduction; if the second material portion 31 has a thickness of less than or equal to 1.0 nm, the effects of the light-emitting element 1 exhibiting a lower drive voltage (power consumption), which will be described later in detail, can be more efficiently achieved. The thickness of the second material portion 31 may be measured through element analysis by, for example, the above-described EDX or EELS.

### Light-Emitting Element: Light-Emitting Layer

Referring back to the schematic cross-sectional view of the light-emitting element 1 in FIG. 1, the light-emitting layer 13 contains, for example, quantum dots 40 as a light-emitting material. In the present disclosure, the term, “quantum dot,” refers to a dot composed of a nanoparticle with a maximum width of less than or equal to 100 nm. The quantum dot may have any shape so long as the shape satisfies this maximum width and does not necessarily have a spherical three-dimensional shape (with a circular cross-sectional shape). The quantum dot may have, for example, a polygonal cross-sectional shape, a virgulate three-dimensional shape, a ramal three-dimensional shape, a three-dimensional shape with an irregular surface, or a combination of any of these shapes.

The quantum dot 40 may have, for example, a core/shell structure including a core and a shell formed around the core. In such a case, the electrons and holes injected to the light-emitting layer 13 recombine in the core of the quantum dot 40, thereby causing the quantum dot 40 to emit light. The light emitted by the quantum dot 40 has a narrow spectrum due to quantum confinement effect and therefore exhibits relatively deep chromaticity. The shell may have a function of restraining, for example, core defects and dangling bonds and reducing recombination of carriers through a deactivation process. It should be understood however that the quantum dot 40 is not necessarily limited to these examples and may alternatively have one of various conventional, publicly known structures. In addition, the light-emitting layer 13 may further include an organic ligand coordinated to the outermost circumferential surface of the quantum dot 40.

In particular, in the light-emitting layer 13 in accordance with the present embodiment, cadmium atoms account for less than or equal to 0.01 wt % of all the atoms in the quantum dots 40 which are a light-emitting material. In other words, the quantum dots 40 contain 0.01 wt % or less cadmium atoms or no cadmium atoms at all. Therefore, the cadmium atom content of the quantum dots 40 in the light-emitting element 1 does not exceed the maximum allowable concentration dictated in the provisions of RoHS (Restriction of the Use of Certain Hazardous Substances in Electrical Equipment), so that the products that include the light-emitting element 1 can be easily disposed of, recycled, or otherwise processed.

It should be understood however that the quantum dots 40 are not necessarily limited to these examples and may be made of any one of various conventional, publicly known materials. As an example, the quantum dots 40 may have, for example, an InP/ZnS, ZnSe/ZnS, or CIGS/ZnS core/shell structure. Note that the quantum dots may include a shell of layers containing a plurality of mutually different materials.

The quantum dots 40 have a particle diameter of approximately from 1 to 100 nm. The wavelength of the light emitted by the quantum dots 40 can be controlled through the particle diameter. In particular, when the quantum dots 40 have a core/shell structure, the wavelength of the light emitted by the quantum dots 40 can be controlled by controlling the particle diameter of the core. Therefore, the wavelength of the light emitted by the light-emitting element 1 can be controlled by controlling the particle diameter of the core of the quantum dots 40.

### Light-Emitting Element: Effects of Electron Transport Layer

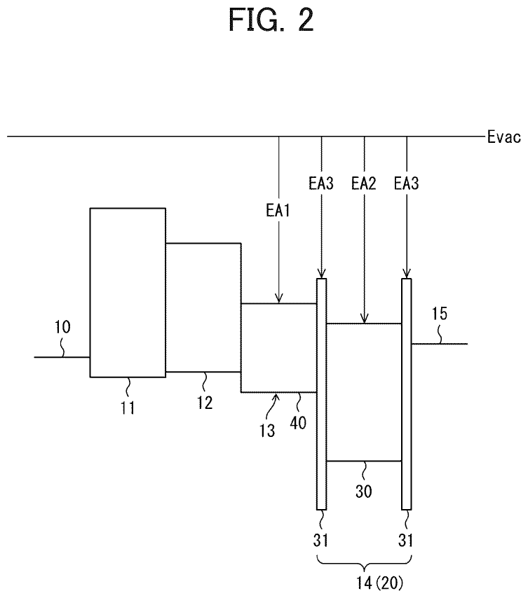

A detailed description is now given of effects of the electron transport layer 14 with reference to FIG. 2. FIG. 2 is an energy band diagram of layers in the light-emitting element 1 in accordance with the present embodiment. FIG. 2 shows the Fermi levels of the anode 10 and the cathode 15. FIG. 2 also shows the bandgaps of the hole injection layer 11, the hole transport layer 12, the light-emitting layer 13, and the electron transport layer 14.

In particular, FIG. 2 shows the bandgap of the quantum dots 40 in the light-emitting layer 13. FIG. 2 shows the bandgaps of the nanoparticles 30 of the first material and the second material portion 31 containing the second material both in the electron transport layer 14. Note that the energy band diagram in FIG. 2 shows the energy levels of the layers, relative to vacuum energy level Evac.

A barrier to the electron injection from the electron transport layer 14 to the light-emitting layer 13 is now discussed with reference to FIG. 2. Here, the electron affinity of the light-emitting layer 13 is denoted by EA1, the electron affinity of the nanoparticles 30 in the electron transport layer 14 is denoted by EA2, and the electron affinity of the second material portion 31 is denoted by EA3. Referring to FIG. 2, in the present embodiment, the electron affinity EA1 of the light-emitting layer 13 is smaller than the electron affinity EA2 of the nanoparticles 30 in the electron transport layer 14 and is larger than the electron affinity EA3 of the second material portion 31. However, the electron affinity EA3 of the second material portion 31 can vary depending on the composition, and there are cases where the electron affinity EA1 of the light-emitting layer 13 is smaller than the electron affinity EA3 of the second material portion 31. The following description will focus on cases where the electron affinity EA1 of the light-emitting layer 13 is smaller than the electron affinity EA3 of the second material portion 31.

Note that the electron affinity EA1 of the light-emitting layer 13 is given by the absolute value of the energy difference between the vacuum energy level Evac and the lower end (CBM) of the conduction band of the light-emitting layer 13. In addition, the electron affinity EA2 of the nanoparticles 30 in the electron transport layer 14 is given by the absolute value of the energy difference between the vacuum energy level Evac and the CBM of the nanoparticles 30 in the electron transport layer 14. The electron affinity EA3 of the second material portion 31 in the electron transport layer 14 is given by the absolute value of the energy difference between the vacuum energy level Evac and the CBM of the second material portion 31 in the electron transport layer 14.

Therefore, that the electron affinity EA1 of the light-emitting layer 13 is smaller than the electron affinity EA2 of the nanoparticles 30 and the electron affinity EA3 of the second material portion 31 in the electron transport layer 14 corresponds to the upper end of the bandgap of the light-emitting layer 13 being higher than the upper ends of the bandgaps of the nanoparticles 30 and the second material portion 31 in the electron transport layer 14 in FIG. 2.

In addition, the bandgap of the second material portion 31 is larger than the bandgap of the nanoparticles 30. In other words, the bandgap of the second material is larger than the bandgap of the first material, and the electron affinity of the second material is smaller than the electron affinity of the first material. Therefore, the difference between the electron affinity EA1 of the light-emitting layer 13 and the electron affinity EA3 of the second material portion 31 is smaller than the difference between the electron affinity EA1 of the light-emitting layer 13 and the electron affinity EA2 of the nanoparticles 30. This corresponds to the fact that the difference between the upper end of the bandgap of the second material portion 31 and the upper end of the bandgap of the light-emitting layer 13 is smaller than the difference between the upper end of the bandgap of the nanoparticles 30 and the upper end of the bandgap of the light-emitting layer 13, as shown in FIG. 2.

In a charge injection type of light-emitting element, the height of the barrier to the injection of electrons from a first layer to a second layer that is adjacent to the first layer is typically given by the energy difference between the CBM of the first layer and the CBM of the second layer and corresponds to the energy obtained by subtracting the electron affinity of the second layer from the electron affinity of the first layer.

Referring to FIG. 2, when the second material portion 31 is provided on the surface of the nanoparticle 30, the barrier to the electron injection from the second material portion 31 to the light-emitting layer 13 is smaller than the barrier to the electron injection from to the nanoparticle 30 to the light-emitting layer 13. Therefore, the electron transport layer 14, by including the nanoparticles 30 and the second material portions 31, can lower the barrier to the electron injection from the electron transport layer 14 to the light-emitting layer 13. Therefore, the light-emitting element 1 transports electrons from the cathode 15 to the light-emitting layer 13 at a lower application voltage owing to the electron transport layer 14, which lowers the drive voltage of the light-emitting element 1.

The electron-injecting property is generally improved by reducing the barrier to electron injection. However, as described above, the second material has a lower electron transport ability than the first material. Therefore, the efficiency of the electron transport from the cathode 15 to the light-emitting layer 13 via the electron transport layer 14 is lower than when the electron transport layer 14 contains only the nanoparticles 30. Therefore, the light-emitting element 1, by reducing electron density in the light-emitting layer 13, can alleviate electron excess in the light-emitting layer 13, thereby improving the charge-carrier balance of the light-emitting layer 13. Therefore, the present embodiment is capable of simultaneously lowering the drive voltage and restraining electron injection owing to the second material which has a lower electron transport ability than the first material.

From the description above, the light-emitting element 1 is capable of improving the charge-carrier balance of the light-emitting layer 13 while lowering the drive voltage, owing to the electron transport layer 14.

### Method of Manufacturing Light-Emitting Element: Until Formation of Light-Emitting Layer

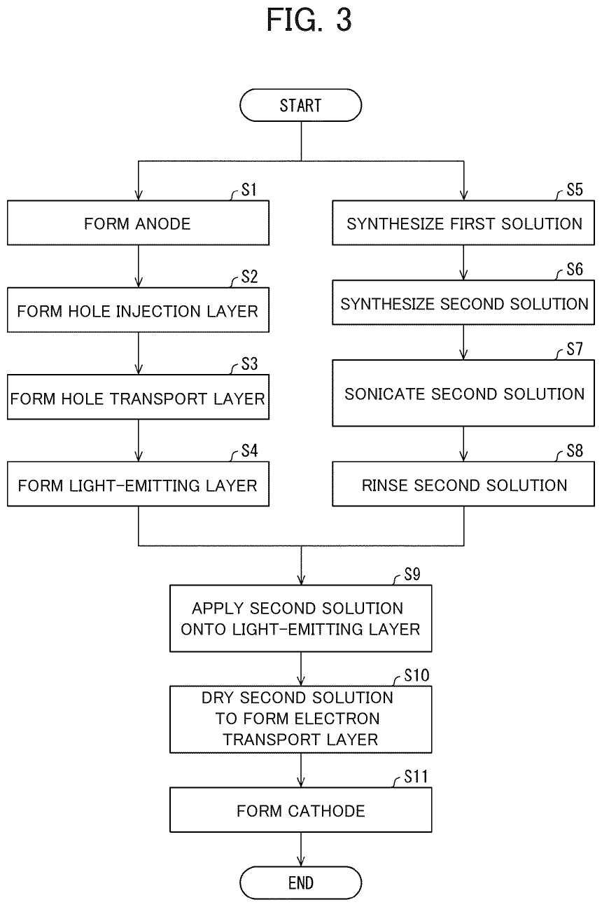

A method of manufacturing the light-emitting element 1 in accordance with the present embodiment will be described with reference to FIG. 3. FIG. 3 is a flow chart representing an exemplary method of manufacturing the light-emitting element 1.

In the method of manufacturing the light-emitting element 1 in accordance with the present embodiment, first, the anode 10 is formed (step S1). The anode 10 may be formed by, for example, forming a film of a conductive material on a substrate by, for example, sputtering. Specifically, the anode 10 may be formed by, for example, forming an ITO thin film measuring 2 mm×10 mm with a thickness of 30 nm on a substrate by sputtering.

Next, the hole injection layer 11 is formed (step S2). The hole injection layer 11 may be formed on the anode 10, for example, either by coating such as spin-coating using a colloidal solution or by, for example, vacuum vapor deposition or sputtering. Specifically, a thin film may be formed by, for example, applying nickel oxide with a particle diameter of 10 nm onto the anode 10 by spin-coating and then drying the applied nickel oxide. Furthermore, the hole injection layer 11 may be formed by bringing, into contact with this thin film, a solution prepared by dissolving MeO-2PACz in ethanol to 0.01 M for at least 5 seconds and then drying the solution.

Next, the hole transport layer 12 is formed (step S3). The hole transport layer 12 may be formed on the hole injection layer 11, for example, either by coating such as spin-coating using a colloidal solution or by, for example, vacuum vapor deposition or sputtering. Specifically, the hole transport layer 12 may be formed by, for example, applying, onto the hole injection layer 11, a solution prepared by dissolving Poly-TPD (8 mg) in chlorobenzene (1 mL) by spin-coating and then drying the applied solution.

Next, the light-emitting layer 13 is formed (step S4). When the light-emitting layer 13 contains the quantum dots 40 as described above, the light-emitting layer 13 may be formed on the hole transport layer 12 by, for example, coating such as spin-coating using a solution in which the quantum dots 40 are dispersed. Specifically, the light-emitting layer 13 may be formed by, for example, applying, onto the hole transport layer 12 by spin-coating, a solution (0.1 mL) in which the quantum dots 40 that have an InP/ZnS core/shell structure and that emit red light are dispersed and then drying the applied solution. The light-emitting layer 13 thus formed may have a thickness of 15 nm.

Note that in the present disclosure, red light is the light with a central emission wavelength in a wavelength range of, for example, from 600 nm, exclusive, to 780 nm, inclusive. Note that when the light-emitting layer 13 contains an organic light-emitting material in place of the quantum dots 40, the light-emitting layer 13 may be formed by, for example, vacuum vapor deposition.

### Method of Manufacturing Light-Emitting Element: Synthesis of Solution

In the method of manufacturing the light-emitting element 1, the electron transport layer 14 is formed after the light-emitting layer 13 is formed. In the present embodiment, the electron transport layer 14 is formed by coating using a solution containing the nanoparticle structural bodies 20 (detailed later). Here, in the method of manufacturing the light-emitting element 1, the solutions used in this coating are synthesized before that coating.

Specifically, in the method of manufacturing the light-emitting element 1, a first solution containing the nanoparticles 30 is synthesized (step S5). The first solution may be synthesized by, for example, adding a first-material-containing precursor to the nanoparticles 30 to a solvent such as ethanol and stirring the resultant mixture.

More specifically, in step S5, first, a solution is synthesized in which zinc acetate dihydrate and magnesium acetate tetrahydrate are dissolved in a molar ratio of 85:15 in dimethyl sulfoxide. Next, a solution in which tetramethyl ammonium hydroxide is dissolved in ethanol may be added to this solution, and the resultant mixture be stirred for 1 hour, to synthesize the first solution in which the zinc oxide-containing nanoparticles 30 are dispersed.

Next, a second solution in which the above-described second material is added to the first solution is synthesized (step S6). Specifically, the second solution may be synthesized by adding so much magnesium acetate tetrahydrate to the first solution as to account for 30 mol % of the solute of the first solution.

Next, the second solution is subjected to sonication (step S7). In this sonication, the second solution is rapidly and quickly treated with heat, and the second material is formed on the surface 30S of the nanoparticles 30 in the second solution by this heat treatment. Hence, the second material portion 31 containing the second material is formed on the surface 30S of the nanoparticles 30 in the second solution, in other words, the nanoparticle structural bodies 20 are synthesized in the second solution.

Next, the second solution is rinsed (step S8). The rinsing of the second solution is done by, for example, adding a suitable solvent to the second solution and subjecting the second solution to centrifuge, thereby removing the first material or the second material not contained in the nanoparticle structural bodies 20 from the second solution. The synthesis of the second solution is hence completed that is used in the coating of the electron transport layer 14. Note that the second solution may be let to stand for a suitable period of time between step S7 and step S8.

### Method of Manufacturing Light-Emitting Element: Identifying Elements in Solution

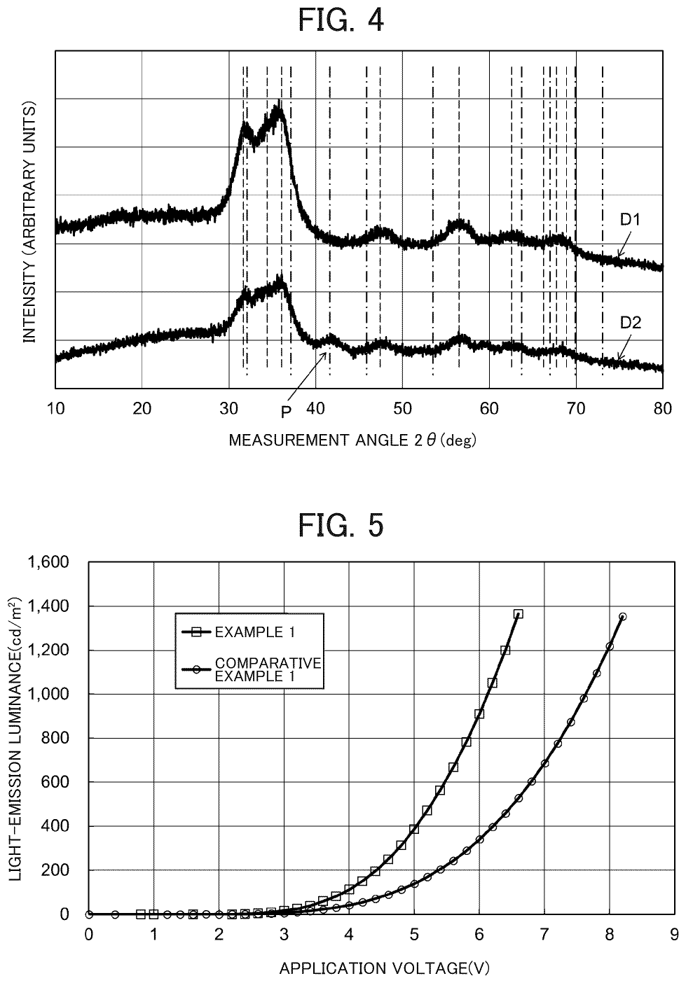

The elements contained in the first solution and the second solution synthesized by the above-described method may be identified by XRD (X-ray diffraction; X-ray diffraction device) on each of the first solution and the second solution. A method of identifying elements by XRD is now described with reference to FIG. 4.

FIG. 4 is a graph representing results of X-ray diffraction spectrum measurement on each of the first solution and the second solution synthesized by the above-described method. In the graph in FIG. 4, the horizontal axis indicates a measurement angle 20 (unit: deg), which is twice the angle of incidence (reflection angle) of an X-ray to a measurement target, and the vertical axis indicates the measured intensity of the X-ray (arbitrary units).

In the present embodiment, spectrum data D1 shown in FIG. 4 was obtained by performing X-ray diffraction spectrum measurement by XRD on the thin film obtained by applying dropwise the first solution synthesized in above-described step S5 onto a substrate and then drying the applied, first solution. In addition, spectrum data D2 shown in FIG. 4 was obtained by performing X-ray diffraction spectrum measurement by XRD on the thin film obtained by applying dropwise the second solution synthesized in above-described step S5 to step S8 onto a substrate and then drying the applied, second solution. Note that an offset was given in the intensity of the two sets of spectrum data in FIG. 4 for easy comparison of the two.

Here, FIG. 4 denotes a zinc oxide reference by a broken line and a magnesium oxide reference by a dash-dot line. In other words, if the sample on which the XRD measurement was made contained zinc oxide, the spectrum data obtained from the measurement showed peaks primarily at the measurement angles indicated by broken lines. Meanwhile, if the sample on which the XRD measurement was made contained magnesium oxide, the spectrum data obtained from the measurement showed peaks primarily at the measurement angles indicated by dash-dot lines.

As can be seen in FIG. 4, both the spectrum data D1 and the spectrum data D2 showed peaks indicating the presence of zinc oxide. This demonstrates that the first solution and the second solution synthesized by the above-described method contained a material that had the crystal structure of zinc oxide. In contrast, the spectrum data D2 showed a peak P indicating the presence of magnesium oxide near a measurement angle of 42°, whereas the spectrum data D1 showed no peak at that measurement angle. This demonstrates that the second solution synthesized by the above-described method contained a material that had the crystal structure of magnesium oxide, whereas the first solution contained no such a material.

Furthermore, the elements contained in the first solution and the second solution may be identified through element analysis, for example, using an ICP-AES (inductively coupled plasma atomic emission spectrometer) or by XPS (X-ray photo-electron spectroscopy).

For instance, it may actually be checked that the first solution contains Mg, by performing element analysis on the first solution synthesized by the above-described method using an ICP-AES or by XPS. In this case, it is understood that although the first solution contained no magnesium oxide, a material had been synthesized that had the crystal structure of zinc oxide and that also contained Mg atoms. In other words, it is understood that in the first solution, the nanoparticles 30 had been synthesized that contained magnesium zinc oxide as the first material. Hence, it is understood that the second solution, synthesized from the first solution, also contained the nanoparticles 30 containing magnesium zinc oxide as the first material.

It was confirmed in this manner that the first solution contained the nanoparticles 30 containing magnesium zinc oxide as the first material. It was also confirmed that the second solution contained the nanoparticles 30 containing magnesium zinc oxide as the first material and the second material portions 31 containing magnesium oxide as the second material.

### Method of Manufacturing Light-Emitting Element: Forming Electron Transport Layer and Cathode

In the method of manufacturing the light-emitting element 1, the second solution is applied onto the light-emitting layer 13 by, for example, spin-coating after step S4 and step S8 are completed (step S9). Next, the electron transport layer 14 containing the nanoparticle structural bodies 20 is formed by drying the applied second solution (step S10). The electron transport layer 14 formed in this manner may have a thickness of 40 nm.

Next, similarly to the anode 10, the cathode 15 is formed by forming a film of a conductive material on the electron transport layer 14 by, for example, sputtering or vacuum vapor deposition (step S11). Specifically, for example, the cathode 15 may be formed by forming a thin film of Ag with a thickness of 50 nm on the electron transport layer 14 by vacuum vapor deposition.

### Summation of Embodiment 1

The light-emitting element 1 in accordance with the present embodiment includes, as an intervening layer, the electron transport layer 14 containing the nanoparticle structural bodies 20. The nanoparticle structural body 20 includes: the nanoparticle 30 of the first material containing a metal oxide; and the second material portion 31 made of the inorganic, second material that has a lower electron transport ability than the first material and formed on at least a part of the surface 30S of the nanoparticle 30.

Therefore, the light-emitting element 1 is capable of lowering the drive voltage and improving the charge-carrier balance of the light-emitting layer 13 owing to the provision of the electron transport layer 14 for the above-described reasons. In addition, the light-emitting element 1 reduces the entire thickness and drive voltage of the light-emitting element 1 in comparison with a case where the light-emitting element 1 has a layered structure that includes a layer of the first material and a layer of the second material as the electron transport layer. Furthermore, the light-emitting element 1 ensures the electrical conduction from he cathode 15 to the light-emitting layer 13 via the electron transport layer 14 and reduces the drive voltage in comparison with a case where the light-emitting element 1 includes an electron transport layer containing nanoparticles of the first material and nanoparticles of the second material.

The electron transport layer 14 in accordance with the present embodiment is formed by applying the second solution. In the present embodiment, the second solution containing the nanoparticle structural bodies 20 in each of which the second material portion 31 is formed on at least a part of the surface of the nanoparticle 30 is synthesized by adding the second material to the first solution containing the nanoparticles 30 and furthermore performing sonication. In other words, in the present embodiment, the nanoparticle structural bodies 20 are synthesized in a state where the first material and the second material are in a solvent all the time. Therefore, in the present embodiment, the nanoparticle structural bodies 20 can be formed while ensuring the dispersibility of the second material and the nanoparticles 30 containing the first material in the second solution.

For instance, there are cases where it is difficult to form an electron transport layer containing nanoparticles of the first material and nanoparticles of the second material from a mixed solution of these nanoparticles due to a difference in dispersibility between the first material and the second material. According to the method of forming the electron transport layer 14 in accordance with the present embodiment, since the nanoparticle structural bodies 20 are synthesized while ensuring the dispersibility of the materials in the second solution, the nanoparticle structural bodies 20 can be readily synthesized even when there is a difference in dispersibility between the first material and the second material.

Therefore, according to the method of manufacturing the light-emitting element 1 in accordance with the present embodiment, since there is a greater design freedom for the first material and the second material, it becomes easier to design the electron transport layer 14 so that the electron transport layer 14 can improve the charge-carrier balance of the light-emitting layer 13. Therefore, the method of manufacturing the light-emitting element 1 in accordance with the present embodiment can provide the light-emitting element 1 that can improve the charge-carrier balance of the light-emitting layer 13.

Furthermore, the method of manufacturing the light-emitting element 1 in accordance with the present embodiment can form the electron transport layer 14 without having to perform sputtering or other like steps that could deactivate the light-emitting material containing the quantum dots 40 for the light-emitting layer 13. In addition, according to the above-described method, the nanoparticle structural bodies 20 can be synthesized by heating the second solution rapidly and only for a short period of time by sonication of the second solution, which enables alleviating damage caused by heating of the materials for the second solution. Therefore, the method of manufacturing the light-emitting element 1 in accordance with the present embodiment can alleviate possible damage of the light-emitting layer 13 and the electron transport layer 14 and provide the light-emitting element 1 with more reliability.

The present embodiment has so far discussed an example of the nanoparticle structural bodies 20 where the second material portion 31 is formed on the entire surface 30S of the nanoparticle 30 as shown in FIG. 1, which is by no means intended to limit the scope of the invention. Alternatively, for example, the second material portion 31 may be formed on at least a part of the surface 30S of the nanoparticle 30.

For instance, in the present embodiment, the second material portion 31 may cover 10% or more of the outer circumference of the nanoparticle 30 as measured in a cross-section of the nanoparticle 30. For example, it may be checked, by element analysis of the aforementioned thin piece obtained by cutting the electron transport layer 14 in the stack direction of the light-emitting element 1, that the second material portion 31 covers 10% or more of the outer circumference of the nanoparticle 30 in a certain location. When this is the case, the uniformity of the particle diameter of the nanoparticle structural bodies 20 is improved, the unevenness of the thickness of the electron transport layer 14 is reduced, and the stability of the path by which electrons are transported in the electron transport layer 14 is improved. In addition, in such a case, since the disruption of the transport of electrons by the second material portion 31 is more likely to occur, the excessive electron richness of the light-emitting layer 13 is further alleviated. Hence, the electron transport layer 14 further alleviates the excessive electron richness of the light-emitting layer 13 and reduces the drive voltage of the light-emitting element 1. Note that the second material portion 31 more preferably covers at least ⅙ of the outer circumference of the nanoparticle 30 as measured in a cross-section of the nanoparticle 30. Throughout the present disclosure, the term, “the ratio of the cover of the outer circumference,” refers to the ratio to the outer circumference as measured in a single cross-section of the nanoparticle 30 and does not refer to a ratio as measured in the three-dimensional surface area of the nanoparticle 30.

Note that the nanoparticles 30 with low uniformity could be obtained in some cases in step S5, depending on conditions in the above-described method of manufacturing the light-emitting element 1. In such a case, a shell layer of the same first material as the first material for the nanoparticles 30 may be formed on the surface of the nanoparticles 30 prior to step S6. The formation of the shell layer improves the uniformity of the nanoparticles 30, which in turn improves the uniformity of the nanoparticle structural bodies 20.

The quantum dots 40 in accordance with the present embodiment do not necessarily contain cadmium as described above. The use of a cadmium-containing light-emitting material can generally deliver good properties. However, the use of a light-emitting material that does not use cadmium as described here can increase safety.

Examples of the cadmium-free quantum dots 40 include the quantum dots with, for example, an InP/ZnS or InP/ZnSe core/shell structure. In some of such cases, a mixed crystal layer in which the indium in the InP in the core of the quantum dot 40 and the zinc in the ZnS or ZnSe of the quantum dot 40 are replaced with each other could be formed between the core and the shell of the quantum dot 40.

In this mixed crystal layer, the core and the shell form a p-n junction. Therefore, this mixed crystal layer does not pose a barrier to the injection of electrons, but could pose a barrier to the injection of holes, in the injection of carriers from the shell to the core of the quantum dot 40. Therefore, in the light-emitting element 1 including the light-emitting layer 13 containing the above-described quantum dots 40, the excessive electron richness of the light-emitting layer 13 could be worsened.

The light-emitting element 1 in accordance with the present embodiment may adopt a structure including: the light-emitting layer 13 containing the cadmium-free quantum dots 40 as a light-emitting material; and the electron transport layer 14 that allows for alleviation of the excessive electron richness of the light-emitting layer 13. Owing to this structure, the light-emitting element 1 can enhance safety while alleviating the excessive electron richness of the light-emitting layer 13 and reducing the drive voltage of the light-emitting layer 13, so that the products that include the light-emitting element 1 can be more easily disposed of, recycled, or otherwise handled.

The light-emitting element 1 in accordance with the present embodiment, as described above, may include the hole injection layer 11 containing an inorganic material. Generally, when the light-emitting element includes a hole injection layer containing an inorganic material, the reliability may be improved, but the excessive electron richness of the light-emitting layer could be worsened because the hole transport efficiency of the hole injection layer is reduced, in comparison with when the light-emitting element includes a hole injection layer containing an organic material.

However, the light-emitting element 1 in accordance with the present embodiment includes the electron transport layer 14 that allows for alleviation of the excessive electron richness of the light-emitting layer 13. Therefore, in the present embodiment, even when the light-emitting element 1 includes the hole injection layer 11 containing an inorganic material as described above, the provision of such an electron transport layer 14 can further enhance the reliability of the light-emitting element 1 while alleviating the excessive electron richness of the light-emitting layer 13.

Furthermore, the light-emitting element 1 in accordance with the present embodiment, as described above, may include the hole transport layer 12 containing an organic material. In such a case, the light-emitting element 1 can improve the hole transport efficiency of the hole transport layer 12 and for this reason further alleviate the excessive electron richness of the light-emitting layer 13, in comparison with when the light-emitting element 1 includes the hole transport layer 12 containing an inorganic material. For example, the light-emitting element 1 may include: the hole injection layer 11 containing an inorganic material; and the hole transport layer 12 containing an organic material. In such a case, the hole injection layer 11 can ensure the reliability, and the hole transport layer 12 can further alleviate the excessive electron richness of the light-emitting layer 13.

### Evaluation of Properties of Light-Emitting Element

The properties of the light-emitting element 1 in accordance with the present embodiment are evaluated by comparing the properties of light-emitting elements in accordance with examples of the invention and the properties of light-emitting elements in accordance with comparative examples. Specifically, light-emitting elements were manufactured in accordance with Example 1 and Comparative Example 1 (both detailed below), and their properties were compared.

The light-emitting element in accordance with Example 1 was a light-emitting element manufactured by the above-described method of manufacturing the light-emitting element 1 in accordance with the present embodiment. Therefore, the light-emitting element in accordance with Example 1 included, in the electron transport layer 14, the nanoparticle structural bodies 20 each including: the nanoparticle 30; and the second material portion 31 formed on at least a part of the surface 30S of the nanoparticle 30.

The light-emitting element in accordance with Comparative Example 1 was a light-emitting element manufactured by partially changing the above-described method of manufacturing the light-emitting element 1 in accordance with the present embodiment, when compared with the light-emitting element in accordance with Example 1. In the method of manufacturing the light-emitting element in accordance with Comparative Example 1, steps S6 to S8 were not performed. Furthermore, in the method of manufacturing the light-emitting element in accordance with Comparative Example 1, an electron transport layer was formed by applying the first solution onto the light-emitting layer 13 in step S9 and drying the first solution in step S10. Therefore, in the light-emitting element in accordance with Comparative Example 1, the electron transport layer contained the nanoparticles 30, but did not contain the second material portions 31.

The properties of the light-emitting element in accordance with Example 1 and the properties of the light-emitting element in accordance with Comparative Example 1 were measured by measuring light-emission luminance while applying, to each light-emitting element, a voltage from 0 V to a voltage at which the current density is approximately equal to 25 mA/cm². The light-emission luminance of each light-emitting element was measured with a spectrophotometer, “Photal MCPD-7000,” manufactured by Otsuka Electronics Co., Ltd. In addition, the application voltage and current density for each light-emitting element were measured with a source meter Type-2400 manufactured by Keithley Instruments.

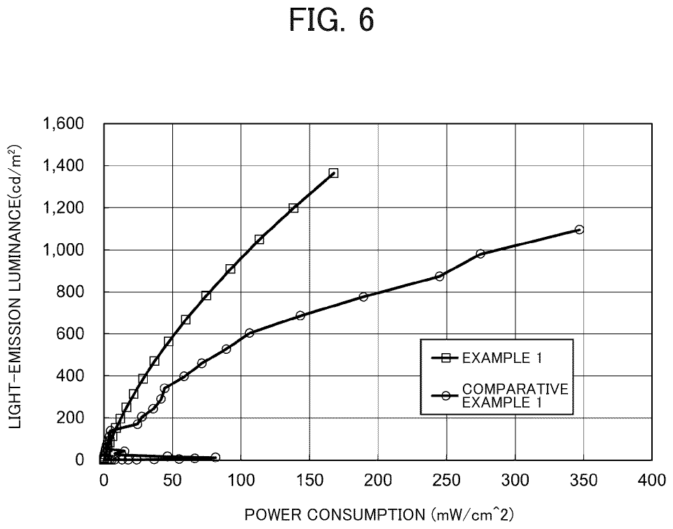

Results of the measurements are shown in graphs in FIGS. 5 and 6. FIG. 5 is a graph representing a relationship between application voltage and light-emission luminance for the light-emitting element in accordance with Example 1 and the light-emitting element in accordance with Comparative Example 1. FIG. 6 is a graph representing a relationship between power consumption calculated from the current density and the application voltage and light-emission luminance for the light-emitting element in accordance with Example 1 and the light-emitting element in accordance with Comparative Example 1. The horizontal axis of the graph indicates the application voltage (unit: V) in FIG. 5 and indicates the power consumption (unit: mW/cm²) in FIG. 6. In addition, the vertical axes of the graphs in FIGS. 5 and 6 indicate the light-emission luminance (unit: cd/m²).

The graph in FIG. 5 shows that the light-emitting element in accordance with Example 1 emits light with a higher luminance than the light-emitting element in accordance with Comparative Example 1 when a voltage higher than approximately 3 V is applied. In addition, the graph in FIG. 6 shows that the light-emitting element in accordance with Example 1 achieves approximately the same luminance as, with a lower power consumption than, the light-emitting element in accordance with Comparative Example 1. Note that in the graph in FIG. 6, the data where almost no luminance is obtained as the data for Comparative Example 1 indicates that there were cases where almost no light was emitted even when a voltage was applied to the light-emitting element in accordance with Comparative Example 1.

These results were obtained presumably because the provision of the electron transport layer 14 containing the nanoparticle structural bodies 20 in the light-emitting element in accordance with Example 1 alleviated the excessive electron richness of the light-emitting layer 13 and improved the external quantum efficiency of the light-emitting layer 13 over the light-emitting element in accordance with Comparative Example 1. The results were obtained also presumably because the provision of the electron transport layer 14 containing the nanoparticle structural bodies 20 in the light-emitting element in accordance with Example 1 reduced the drive voltage required of the light-emitting element to obtain the same luminance and reduced the total power consumption of the light-emitting element, over the light-emitting element in accordance with Comparative Example 1.

In particular, the electron transport layer 14 of the light-emitting element in accordance with Example 1 contains: the nanoparticles 30 containing magnesium zinc oxide as the first material; and the second material portions 31 containing a metal oxide as the second material. Since magnesium zinc oxide is soluble in alkali, the process tolerance can be improved by forming the second material portions 31 containing a metal oxide other than magnesium zinc oxide which is tolerant to alkali.

The metal oxide used as the second material and tolerant to alkali is, for example, aluminum oxide (e.g., Al₂O₃). Note that as described earlier, the compositions found in the chemical formulae in the present disclosure are desirably stoichiometric. It should be understood however that the present disclosure does not exclude non-stoichiometric compositions.

In addition, the electron transport layer 14 in the light-emitting element in accordance with Example 1 includes the second material portion 31 containing a highly transmissive magnesium oxide as the second material. Therefore, when the light-emitting element has a top-emission structure in which light is taken out from the light-emitting layer 13 through the cathode 15, the electron transport layer 14 in accordance with Example 1 reduces the absorption of the light from the light-emitting layer 13 by the second material portions 31 in the electron transport layer 14. Therefore, the light-emitting element in accordance with Example 1 achieves a further enhanced light extraction efficiency.

### Embodiment 2

The following will describe another embodiment of the present disclosure. Throughout the following, for convenience of description, members of an embodiment that have the same arrangement and function as members of a specific preceding embodiment are denoted by the same reference numerals and description thereof is not repeated.

### Variation Example of Nanoparticle Structural Body

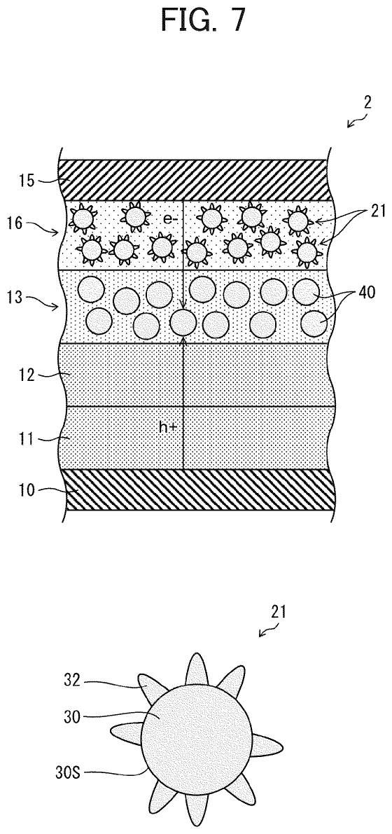

FIG. 7 is an aligned pair of a schematic cross-sectional view of a light-emitting element 2 in accordance with the present embodiment and a schematic cross-sectional view of a nanoparticle structural body 21 (detailed later) in accordance with the present embodiment. Note that the schematic cross-sectional view of the light-emitting element 2 in FIG. 7 shows a cross-section that corresponds to the schematic cross-sectional view of the light-emitting element 1 in FIG. 1. In addition, the schematic cross-sectional view of the nanoparticle structural body 21 in FIG. 7, similarly to the schematic cross-sectional view of the nanoparticle structural body 20 in FIG. 1, shows a cross-section of the nanoparticle structural body 21 that passes through the center of the nanoparticle 30 for the sake of simplicity.

The light-emitting element 2 in accordance with the present embodiment differs in structure from the light-emitting element 1 in accordance with Embodiment 1 only in that the former includes an electron transport layer 16 in place of the electron transport layer 14. The electron transport layer 16 differs in structure from the electron transport layer 14 only in that the former includes the nanoparticle structural bodies 21 in place of the nanoparticle structural bodies 20. In other words, the electron transport layer 16, similarly to the electron transport layer 14, transports the electrons e injected from the cathode 15 to the light-emitting layer 13.

The nanoparticle structural body 21 includes a second material portion 32 formed insularly on the surface 30S of the nanoparticle 30. The second material portion 32 is made of the same material as the second material portion 31 in accordance with Embodiment 1, in other words, is made of the second material.

Therefore, the electron transport layer 16 is an intervening layer including: the nanoparticles 30 made of the first material containing a metal oxide; and the second material portions 32 made of the inorganic, second material with a lower electron transport ability than the first material and positioned insularly on parts of the surfaces 30S of the nanoparticles 30. Therefore, the light-emitting element 2 can reduce the drive voltage and improve the charge-carrier balance of the light-emitting layer 13, owing to the electron transport layer 16, for the same reasons as those described in Embodiment 1.

Note that the structure of the electron transport layer 16 may be analyzed by the same method as the above-described structure of the electron transport layer 14. Specifically, the electron transport layer 16 may be subjected to element analysis by cutting the electron transport layer 16 in the stack direction of the light-emitting element 2 into a thin piece, observing this thin piece by, for example, TEM, and performing element analysis by, for example, EDX or EELS. Note that EELS is used also in the present embodiment if EDX is not feasible in the measurement.

Assume, for instance, that it has been confirmed that in the above-described thin piece, a portion of the outer circumference of a member containing the first material is formed, and at least a part of the member containing the second material is formed in a plurality of locations. In such a case, the electron transport layer 16 may be determined to contain the nanoparticle structural bodies 21 including: the nanoparticles 30 of the first material; and the second material portions 32 positioned insularly on the surfaces 30S of these nanoparticles 30. As described here, that the second material portions 32 are positioned insularly on the surfaces 30S of the nanoparticles 30 is equal to the second material portions 32 being positioned insularly on the outer circumferences of the nanoparticles 30 in a cross-section of the nanoparticles 30. As described here, that the electron transport layer 16 has the structure of the nanoparticle structural body 21 can be confirmed by, for example, the above-described element analysis on a thin piece. In addition, “the outer circumference of a member” in this case refers also to a space up to 2 nm from the edge of the member. In other words, to confirm that the nanoparticle structural body 21 includes: the nanoparticle 30 containing the first material; and the second material portion 32 positioned insularly on the surface 30S of the nanoparticle 30, one needs only to confirm that at least a part of the member containing the second material is formed in a part of a space up to 2 nm from at least a part of the edge of the member containing the first material and in a plurality of locations.

The thickness of the second material portion 32, in other words, the thickness from the surface 30S of the nanoparticle 30 to the outermost circumference of the nanoparticle structural body 21 may be from 0.4 nm to 2.0 nm, both inclusive, and may be from 0.4 nm to 1.0 nm, both inclusive. If the second material portion 32 has a thickness of greater than or equal to 0.4 nm, the second material portion 32 can be more reliably formed on the surface 30S of the nanoparticle 30 by the method detailed later. In addition, if the second material portion 32 has a thickness of less than or equal to 2.0 nm, carriers can move by tunnel conduction; if the second material portion 32 has a thickness of less than or equal to 1.0 nm, the effects of the light-emitting element 2 exhibiting a lower drive voltage (power consumption) can be more efficiently achieved. The thickness of the second material portion 32 may be measured through the above-described element analysis by, for example, EDX or EELS.

Note that the second material portion 32 may cover 10% or more of the outer circumference of the nanoparticle 30 as measured in a cross-section of the nanoparticle 30, similarly to the second material portion 31. For example, it may be checked, by element analysis of the thin piece obtained by cutting the electron transport layer 14 in the stack direction of the light-emitting element 1, that the second material portion 32 covers 10% or more of the outer circumference of the nanoparticle 30 in a certain location.

In addition, the nanoparticle structural body 21 may have a structure in which the second material portion 32 covers 90% or less of the outer circumference of the nanoparticle 30 as measured in a cross-section of the nanoparticle 30. The confirmation of the structure may be done by, for example, confirming that the second material portion 32 covers 90% or less of the outer circumference of the nanoparticle 30 in a certain location through element analysis of the above-described thin piece.

The present embodiment can reduce the effective particle diameter of the nanoparticle structural body 21 owing to the second material portion 32 being insularly positioned on the outer circumference of the nanoparticle 30 in a cross-section of the nanoparticle 30 as described above, in comparison with when the second material portion 32 covers the entire outer circumference of the nanoparticle 30. Therefore, the present embodiment can reduce increases in the particle diameter of the nanoparticle structural bodies in the electron transport layer 16. Therefore, the present embodiment can further reduce the application voltage for the light-emitting element 2 by improving the concentration of the nanoparticle structural bodies 21 in the electron transport layer 16 and improving the electron transport efficiency of the electron transport layer 16.

The light-emitting element 2 allows for controlling the extent of electron transport disruption by the second material portions 32, by suitably changing conditions in the aforementioned method of manufacturing and hence changing the ratio of the second material portion 32 covering the outer circumference of the nanoparticle 30 in a cross-section of the nanoparticle 30. Therefore, the light-emitting element 2 can more readily both alleviate the excessive electron richness of the light-emitting layer 13 and reduce the application voltage of the light-emitting layer 13.

The light-emitting element 2 in accordance with the present embodiment may be manufactured by partially changing the method of manufacturing the light-emitting element 1 in accordance with Embodiment 1. For example, in the method of manufacturing the light-emitting element 2, the light-emitting element 2 may be manufactured by suitably changing, for example, the concentration or type of the second material added to the first solution in step S6 or sonication conditions in step S7 in the method of manufacturing the light-emitting element 1.

Therefore, in the method of manufacturing the light-emitting element 2 in accordance with the present embodiment, as described in Embodiment 1, the nanoparticle structural bodies 20 can be synthesized while ensuring the dispersibility of the materials in the second solution. Therefore, the nanoparticle structural bodies 20 can be readily synthesized also in the present embodiment even when there is a difference in dispersibility between the first material and the second material. Therefore, the method of manufacturing the light-emitting element 2 in accordance with the present embodiment can provide the light-emitting element 2 that allows for improving the charge-carrier balance of the light-emitting layer 13 for the same reasons as those described in Embodiment 1.

### Embodiment 3

Light-Emitting Element with No Hole Injection Layer

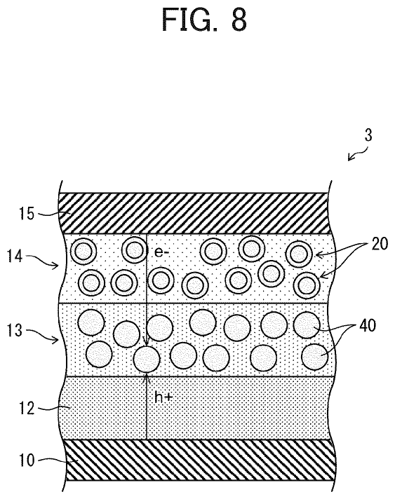

FIG. 8 is a schematic cross-sectional view of a light-emitting element 3 in accordance with the present embodiment. Note that the schematic cross-sectional view of the light-emitting element 3 in FIG. 8 shows a cross-section that corresponds to the schematic cross-sectional view of the light-emitting element 1 in FIG. 1.

The light-emitting element 3 in accordance with the present embodiment differs in structure from the light-emitting element 1 in accordance with aforementioned Embodiment 1 only in that the former includes no hole injection layer 11. In other words, in the present embodiment, the holes from the anode 10 are injected to the hole transport layer 12 and transported to the light-emitting layer 13 via the hole transport layer 12.

The light-emitting element 3 in accordance with the present embodiment includes an electron transport layer 14 containing nanoparticle structural bodies 20 similarly to the light-emitting element 1. Therefore, the light-emitting element 3 in accordance with the present embodiment can also improve the charge-carrier balance of the light-emitting layer 13 while reducing the drive voltage owing to the electron transport layer 14, for the same reasons as those described above. Furthermore, the light-emitting element 3 in accordance with the present embodiment includes no hole injection layer 11 when compared with the light-emitting element 1 or the light-emitting element 2. Therefore, the light-emitting element 3 can further reduce the electrode-to-electrode thickness and for this reason further reduce the drive voltage.

In the present embodiment, the hole transport layer 12 may contain the above-described inorganic hole-transportable material. As described here, the light-emitting element 3 in accordance with the present embodiment may have a structure including: the hole transport layer 12 containing an inorganic material; and the electron transport layer 14 that allows for alleviation of the excessive electron richness of the light-emitting layer 13. Owing to this structure, the light-emitting element 3 enables further increasing the reliability of the light-emitting element 1 while alleviating the excessive electron richness of the light-emitting layer 13 for the same reasons as those described above.

The light-emitting element 3 in accordance with the present embodiment may be manufactured by the same method as the above-described method of manufacturing the light-emitting element 1, except that step S2 alone is omitted. In other words, in the present embodiment, the hole transport layer 12 may be formed on the anode 10. Therefore, the method of manufacturing the light-emitting element 3 in accordance with the present embodiment can provide the light-emitting element 2 that allows for improving the charge-carrier balance of the light-emitting layer 13 for the same reasons as those described in the aforementioned embodiments.

### Embodiment 4

### Display Device

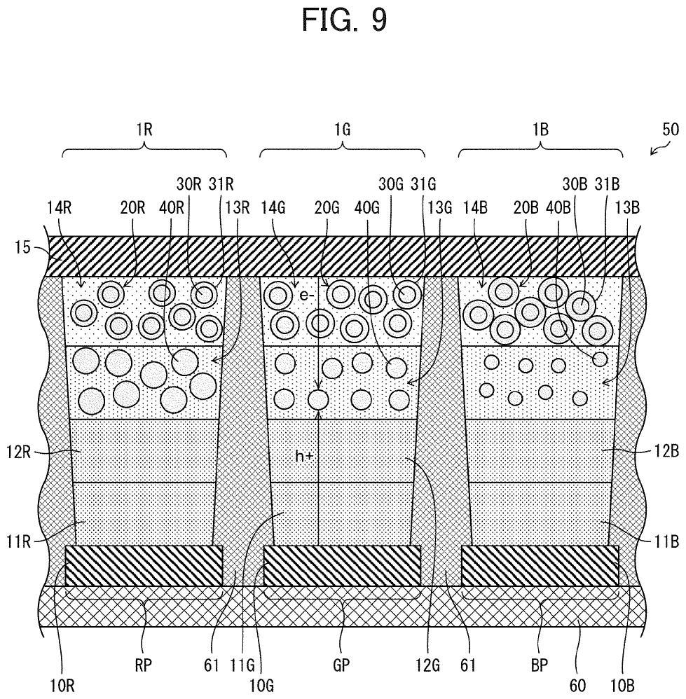

A description is now given of a display device including the above-described light-emitting elements 1 in another embodiment of the present disclosure. FIG. 9 is a schematic cross-sectional view of a display device 50 in accordance with the present embodiment.

The display device 50 in accordance with the present embodiment includes a plurality of light-emitting elements in a plurality of subpixels respectively and produces a display by individually driving the light-emitting elements. The display device 50 includes a plurality of red light-emitting elements 1R that emit red light, a plurality of green light-emitting elements 1G that emit green light, and a plurality of blue light-emitting elements 1B that emit blue light as will be described later in detail. FIG. 9 shows a cross-section of the display device 50 that passes layers in one red light-emitting element 1R, one green light-emitting element 1G, and one blue light-emitting element 1B in the stack direction of the light-emitting elements in the display device 50.

Each red light-emitting element 1R includes an anode 10R, a hole injection layer 11R, a hole transport layer 12R, a red light-emitting layer 13R, an electron transport layer 14R, and a cathode 15, all of which are provided in this order when viewed from below. Each green light-emitting element 1G includes an anode 10G, a hole injection layer 11G, a hole transport layer 12G, a green light-emitting layer 13G, an electron transport layer 14G, and the cathode 15, all of which are provided in this order when viewed from below. Each blue light-emitting element 1B includes an anode 10B, a hole injection layer 11B, a hole transport layer 12B, a blue light-emitting layer 13B, an electron transport layer 14B, and the cathode 15, all of which are provided in this order when viewed from below.

At least one of the red light-emitting element 1R, the green light-emitting element 1G, and the blue light-emitting element 1B may have the same structure as the light-emitting element 1 in accordance with Embodiment 1, except for the color of the light emitted by each light-emitting layer and the structure of each electron transport layer. In addition, the red light-emitting element 1R, the green light-emitting element 1G, and the blue light-emitting element 1B may include the common cathode 15. FIG. 9 shows an example where the red light-emitting element 1R, the green light-emitting element 1G, and the blue light-emitting element 1B have the same structure with each other, except for the color of the light emitted by each light-emitting layer and the structure of each electron transport layer.

Specifically, the red light-emitting layer 13R in the red light-emitting element 1R includes red light-emitting, red quantum dots 40R. The green light-emitting layer 13G in the green light-emitting element 1G includes green light-emitting, green quantum dots 40G. The blue light-emitting layer 13B in the blue light-emitting element 1B includes blue light-emitting, blue quantum dots 40B. The red quantum dots 40R, the green quantum dots 40G, and the blue quantum dots 40B may have the same structure as the quantum dots 40, except for the color of the emitted light. The color of the light emitted by each quantum dot may be changed by changing the particle diameter of that quantum dot.

Note that red light refers to the light that has a central emission wavelength in a wavelength range of from 600 nm, exclusive, to 780 nm, inclusive, as described earlier. In addition, green light refers to, for example, the light that has a central emission wavelength in a wavelength range of 500 nm, exclusive, to 600 nm, inclusive. Furthermore, blue light refers to, for example, the light that has a central emission wavelength in a wavelength range of from 400 nm to 500 nm, both inclusive.

In addition, the red light-emitting element 1R, the green light-emitting element 1G, and the blue light-emitting element 1B shown in FIG. 9 contain, in the respective electron transport layers, nanoparticle structural bodies that have the structure describe in Embodiment 1. The electron transport layer 14R in the red light-emitting element 1R contains nanoparticle structural bodies 20R. The electron transport layer 14G in the green light-emitting element 1G contains nanoparticle structural bodies 20G. The electron transport layer 14B in the blue light-emitting element 1B contains nanoparticle structural bodies 20B. Note that the nanoparticle structural bodies 20R, the nanoparticle structural bodies 20G, and the nanoparticle structural bodies 20B may have the same structure as the nanoparticle structural bodies 20 in accordance with Embodiment 1, except for the ratio of the second material portion 32 covering the outer circumference of the nanoparticle 30 or the thickness of the second material portion 31 in a cross-section of the nanoparticle 30.

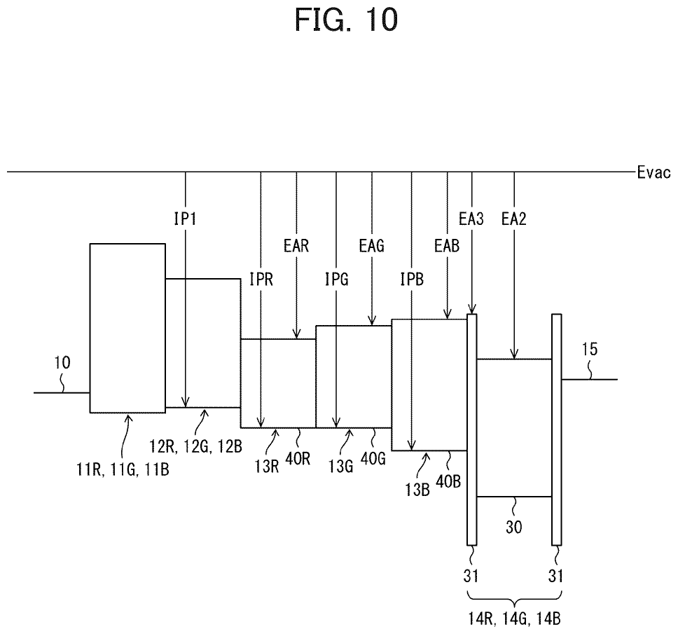

Of two of the red light-emitting element 1R, the green light-emitting element 1G, and the blue light-emitting element 1B, the light-emitting element that has a shorter emission wavelength is designated a short-wavelength element, and the emission wavelength that has a longer emission wavelength is designated a long-wavelength element. In such a case, in the present embodiment, the ratio of the cross-sectional area of the second material to the cross-sectional area of the first material in the electron transport layer of each light-emitting element is lower in the short-wavelength element than in the long-wavelength element. This arrangement, as described in detail in the description of FIG. 10 below, enables adjusting the charge-carrier balance and further reducing the drive voltage (power consumption) of the light-emitting element.

For instance, the ratio of the cross-sectional area of the second material to the cross-sectional area of the first material is lower in the electron transport layer 14R than in the electron transport layer 14G. Alternatively, the ratio of the cross-sectional area of the second material to the cross-sectional area of the first material is lower in the electron transport layer 14G than in the electron transport layer 14B. Alternatively, the ratio of the cross-sectional area of the second material to the cross-sectional area of the first material is lower in the electron transport layer 14R than in the electron transport layer 14B.

In the present embodiment, the ratio of the cross-sectional area of the second material to the cross-sectional area of the first material in the electron transport layer of each light-emitting element may be changed by changing the ratio of the second material portion 32 covering the outer circumference of the nanoparticle 30 in a cross-section of the nanoparticle 30 in each electron transport layer. In addition, the ratio of the cross-sectional area of the second material to the cross-sectional area of the first material in the electron transport layer of each light-emitting element may be changed by changing the thickness of the second material portion 31 in each electron transport layer. For example, the proportion of the segment of the surface 30S of the nanoparticle 30 where the second material portion 31 is formed or the thickness of the second material portion 31 may be lowered in the long-wavelength element over in the short-wavelength element.

The display device 50 includes a substrate 60. The substrate 60 includes a plurality of red subpixels RP, a plurality of green subpixels GP, and a plurality of blue subpixels BP formed thereon. There are provided a plurality of light-emitting elements on the substrate 60: in particular, the red light-emitting element 1R in each red subpixel RP, the green light-emitting element 1G in each green subpixel GP, and the blue light-emitting element 1B in each blue subpixel BP.

The red light-emitting element 1R, the green light-emitting element 1G, and the blue light-emitting element 1B are arranged so as to have their anodes provided toward the substrate 60. Therefore, on the substrate 60, the anodes of the light-emitting elements are provided insularly in respective subpixels, and the cathode 15 is provided commonly to the plurality of subpixels. The display device 50 individually causes the light-emitting elements to emit light by keeping the cathode 15 at a prescribed electrical potential and individually driving the cathodes on the substrate 60 by means of, for example, TFT's (not shown) provided in the respective subpixels on the substrate 60. Hence, the display device 50 is capable of full color displays.

The display device 50 includes a bank 61. The bank 61 is provided on the substrate 60 and divides from the anodes to the electron transport layers in the light-emitting elements for each subpixel in the display device 50. For example, the bank 61 may be provided in a position overlapping the edges of the anodes to alleviate electric field concentration near the edges of the anodes of the light-emitting elements. The bank 61 may be made of a resin material such as polyimide and may contain a photosensitive resin.

The display device 50 in accordance with the present embodiment may be manufactured by preparing the substrate 60 and thereafter forming the light-emitting elements on this substrate 60 by the same method as the method of manufacturing the light-emitting element 1 in accordance with Embodiment 1.

More specifically, for example, first, a thin film for the anodes is formed on the substrate 60 and thereafter patterned for each subpixel. Next, the bank 61 is formed on the substrate 60 and the anodes by photolithography using, for example, a photosensitive resin. Next, the hole injection layer, the hole transport layer, the light-emitting layer, and the electron transport layer for each light-emitting element are formed in each subpixel by, for example, individual coating with different materials such as inkjet printing or patterning by photolithography using a photosensitive resist. Next, the cathode 15, which is common to the plurality of subpixels, is formed by, for example, sputtering. The display device 50 may be manufactured in this manner.

Note that the color of the light emitted by each light-emitting layer may be changed by changing the particle diameter of the quantum dots contained in the layer formed in the step of forming each light-emitting layer. In addition, either the proportion of the segment of the surface 30S of the nanoparticle 30 where the second material portion 31 is formed or the thickness of the second material portion 31 in the electron transport layers may be changed by changing, for example, the concentration of the second material added to the first solution in the step of forming the electron transport layers.

FIG. 10 is an energy band diagram of layers in the display device 50 shown in FIG. 9. FIG. 10 shows the Fermi levels of the anode 10 and the cathode 15. FIG. 10 also shows the bandgaps of the hole injection layer 11R, the hole injection layer 11G, the hole injection layer 11B, the hole transport layer 12R, the hole transport layer 12G, the hole transport layer 12B, the red light-emitting layer 13R, the green light-emitting layer 13G, the blue light-emitting layer 13B, the electron transport layer 14R, the electron transport layer 14G, and the electron transport layer 14B.

As described earlier, the red light-emitting element 1R, the green light-emitting element 1G, and the blue light-emitting element 1B shown in FIG. 9 have the same structure with each other, except for the color of the light emitted by each light-emitting layer and the structure of each electron transport layer. Therefore, in FIG. 10, the same material is used in the hole injection layer 11R, the hole injection layer 11G, and the hole injection layer 11B. In addition, in FIG. 10, the same material is used in the hole transport layer 12R, the hole transport layer 12G, and the hole transport layer 12B. Therefore, the bandgap of the hole injection layer 11R, the bandgap of the hole injection layer 11G, and the bandgap of the hole injection layer 11B are equal to each other. Likewise, the bandgap of the hole transport layer 12R, the bandgap of the hole transport layer 12G, and the bandgap of the hole transport layer 12B are equal to each other.

Note that in the present embodiment, as described earlier, the ratio of the cross-sectional area of the second material to the cross-sectional area of the first material in the electron transport layer of each light-emitting element is changed for each emission wavelength of the light-emitting elements. It should be understood however that, for convenience of description, FIG. 10 shows bandgaps, assuming that the electron transport layer 14R, the electron transport layer 14G, and the electron transport layer 14B have the same structure with each other and also that the same material is used in the electron transport layer 14R, the electron transport layer 14G, and the electron transport layer 14B.

In addition, FIG. 10 shows the bandgap of the red quantum dots 40R in relation to the red light-emitting layer 13R, the bandgap of the green quantum dots 40G in relation to the green light-emitting layer 13G, and the bandgap of the blue quantum dots 40B in relation to the blue light-emitting layer 13B. In addition, FIG. 10 shows the bandgaps of the nanoparticles 30 made of the first material and the second material portions 31 made of the second material in relation to the electron transport layer 14. Note that the energy band diagram in FIG. 10 likewise shows the energy levels of the layers, relative to the vacuum energy level Evac.

As described earlier, the color of the light emitted by the quantum dots may be changed by changing the particle diameter of the quantum dots. The particle diameter of quantum dots decreases with a decrease in the emission wavelength. Therefore, as shown in FIG. 9, the green quantum dots 40G have a smaller particle diameter than do the red quantum dots 40R, and the blue quantum dots 40B have a smaller particle diameter than do the green quantum dots 40G. Therefore, shorter emission wavelengths make it difficult to inject holes to the light-emitting layer, creating a further excess of electrons.

In addition, let IP1 be the ionization potential of the hole transport layer 12, IPR be the ionization potential of the red light-emitting layer 13R, IPG be the ionization potential of the green light-emitting layer 13G, and IPB be the ionization potential of the blue light-emitting layer 13B. Referring to FIG. 10, in the present embodiment, the ionization potential IP1 of the hole transport layer 12 is smaller than the ionization potential IPR of the red light-emitting layer 13R, the ionization potential IPG of the green light-emitting layer 13G, and the ionization potential IPB of the blue light-emitting layer 13B.

Note that the ionization potential IP1 of the hole transport layer 12 is given by the absolute value of the energy difference between the vacuum energy level Evac and the upper end (VBM) of the valence band of the hole transport layer 12. In addition, the ionization potential IPR of the red light-emitting layer 13R is given by the absolute value of the energy difference between the vacuum energy level Evac and the VBM of the red light-emitting layer 13R. The ionization potential IPG of the green light-emitting layer 13G is given by the absolute value of the energy difference between the vacuum energy level Evac and the VBM of the green light-emitting layer 13G. The ionization potential IPB of the blue light-emitting layer 13B is given by the absolute value of the energy difference between the vacuum energy level Evac and the VBM of the blue light-emitting layer 13B.

Generally, when holes are injected from the first layer to the second layer adjacent to the first layer in a charge injection type of light-emitting element, the injection barrier height is given by the energy difference between the VBM of the second layer and the VBM of the first layer and corresponds to the energy obtained by subtracting the ionization potential of the first layer from the ionization potential of the second layer.

Referring to FIG. 9, the ionization potential IPB of the blue light-emitting layer 13B is greater than the ionization potential IPR of the red light-emitting layer 13R and the ionization potential IPG of the green light-emitting layer 13G. Therefore, the hole injection barrier from the hole transport layer 12 to the blue light-emitting layer 13B is greater than the hole injection barrier from the hole transport layer 12 to the red light-emitting layer 13R and the hole injection barrier from the hole transport layer 12 to the green light-emitting layer 13G. In addition, the bandgap increases with a decrease in the particle diameter. Referring to FIG. 10, the bandgap of the blue light-emitting layer 13B is greater than the bandgap of the green light-emitting layer 13G, and the bandgap of the green light-emitting layer 13G is greater than the bandgap of the red light-emitting layer 13R. Therefore, as described above, shorter emission wavelengths make it difficult to inject holes to the light-emitting layer, creating a further excess of electrons.

Accordingly, in the present embodiment, as described above, the ratio of the cross-sectional area of the second material to the cross-sectional area of the first material in the electron transport layer 14B is rendered greater than the ratio of the cross-sectional area of the second material to the cross-sectional area of the first material in the electron transport layer 14G and the ratio of the cross-sectional area of the second material to the cross-sectional area of the first material in the electron transport layer 14R. Hence, the electron restraining effect of the blue light-emitting element 1B can be increased over the electron restraining effect of the green light-emitting element 1G and the electron restraining effect of the red light-emitting element 1R.

In addition, by rendering the ratio of the cross-sectional area of the second material to the cross-sectional area of the first material in the electron transport layer 14G greater than the ratio of the cross-sectional area of the second material to the cross-sectional area of the first material in the electron transport layer 14R, the electron restraining effect of the green light-emitting element 1G can be increased over the electron restraining effect of the red light-emitting element 1R.

By changing the ratio of the cross-sectional area of the second material to the cross-sectional area of the first material as described here and thereby increasing the electron restraining effect, the charge-carrier balance can be adjusted, and the drive voltage can be further reduced.

In addition, in FIG. 10, let EAR be the electron affinity of the red light-emitting layer 13R, EAG be the electron affinity of the green light-emitting layer 13G, and EAB be the electron affinity of the blue light-emitting layer 13B. Referring to FIG. 10, in the present embodiment, the electron affinity EAB of the blue light-emitting layer 13B is smaller than the electron affinity EAG of the green light-emitting layer 13G, and the electron affinity EAG of the green light-emitting layer 13G is smaller than the electron affinity EAR of the red light-emitting layer 13R.

Therefore, the electron injection barrier from the second material portion 31B to the blue light-emitting layer 13B in the electron transport layer 14B is higher than the electron injection barrier from the second material portion 31G to the green light-emitting layer 13G in the electron transport layer 14G. In addition, the electron injection barrier from the second material portion 31G to the green light-emitting layer 13G in the electron transport layer 14G is higher than the electron injection barrier from the second material portion 31R to the red light-emitting layer 13R in the electron transport layer 14R. Therefore, referring to FIG. 10, when the electron transport layer 14R, the electron transport layer 14G, and the electron transport layer 14B have the same structure with each other and the same material is used in the electron transport layer 14R, the electron transport layer 14G, and the electron transport layer 14B, the drive voltage is higher for the green light-emitting element 1G than for the red light-emitting element 1R and is higher for the blue light-emitting element 1B than for the green light-emitting element 1G. Note that FIG. 10 shows a case where the electron affinity EAR of the red light-emitting layer 13R, the electron affinity EAG of the green light-emitting layer 13G, and the electron affinity EAB of the blue light-emitting layer 13B are greater than the electron affinity EA3 of the second material portion 31. However, the electron affinity EA3 of the second material portion 31 can vary depending on the composition, and there are cases where the electron affinity EAR of the red light-emitting layer 13R, the electron affinity EAG of the green light-emitting layer 13G, and the electron affinity EAB of the blue light-emitting layer 13B are smaller than the electron affinity EA3 of the second material portion 31. This example discusses, as an example, a case where the electron affinity of each light-emitting layer is smaller than the electron affinity EA3 of the second material portion 31.

In such a case, to further reduce the application voltage of the display device 50, the drive voltage of the blue light-emitting layer 13B is preferably further reduced. The present embodiment, by providing the above-described second material portion 31B on the surface of a nanoparticle 30B as described above, can lower the electron injection barrier from the second material portion 31B to the blue light-emitting layer 13B in the electron transport layer 14B, thereby reducing the drive voltage of the blue light-emitting element 1B, while restraining electron injection, as described earlier.

According to the analysis by the inventors of the present invention, for example, even when a light-emitting material is used that contains no cadmium and that emits blue light, the drive voltage of the blue light-emitting element 1B can be reduced by providing, on the surface of the nanoparticles 30B made of the first material, the second material portion 31B made of the inorganic, second material that has a lower electron transport ability than the first material.

In addition, in so doing, it has been confirmed that the drive voltage can be reduced further by adding so much magnesium acetate tetrahydrate as to account for 50 mol % of the solute of the first solution in step S7 described above than by adding so much magnesium acetate tetrahydrate as to account for 30 mol % of the solute of the first solution.

The present disclosure is not limited to the description of the embodiments above and may be altered within the scope of the claims. Embodiments based on a proper combination of technical means disclosed in different embodiments are encompassed in the technical scope of the disclosure. Furthermore, new technical features can be created by combining different technical means disclosed in the embodiments.

### REFERENCE SIGNS LIST

1, 2, 3 Light-emitting Element
1B Blue Light-emitting Element
1G Green Light-emitting Element
1R Red Light-emitting Element
10, 10B, 10G, 10R Anode
11, 11B, 11G, 11R Hole Injection Layer
12, 12B, 12G, 12R Hole Transport Layer
13 Light-emitting Layer
13B Blue Light-emitting Layer (Light-emitting Layer)
13G Green Light-emitting Layer (Light-emitting Layer)
13R Red Light-emitting Layer (Light-emitting Layer)
14, 14B, 14G, 14R, 16 Electron Transport Layer (Intervening Layer)
15 Cathode
20, 20B, 20G, 20R, 21 Nanoparticle Structural Body
30, 30B Nanoparticle
30S Surface
31, 31B, 31G, 31R, 32 Second Material Portion
50 Display Device
60 Substrate

1. A light-emitting element comprising:
an anode;
a cathode;
a light-emitting layer between the anode and the cathode; and
an intervening layer between the light-emitting layer and the cathode, wherein
the intervening layer includes:
at least one nanoparticle made of a first material containing a metal oxide; and
a second material portion made of an inorganic, second material that has a lower electron transport ability than the first material and provided on at least a part of a surface of the at least one nanoparticle,
the second material contains a metal oxide.

2. A light-emitting element comprising:
an anode;
a cathode;
a light-emitting layer between the anode and the cathode; and
an intervening layer between the light-emitting layer and the cathode, wherein
the intervening layer includes:
at least one nanoparticle made of a first material containing at least one species selected from the group including zinc oxide, magnesium zinc oxide, lithium zinc oxide, titanium oxide, and strontium titanium oxide; and
a second material portion made of a second material containing at least one species selected from the group including magnesium oxide, zirconium oxide, aluminum oxide, yttrium oxide, and silicon oxide and provided on at least a part of a surface of the at least one nanoparticle.

3. A light-emitting element comprising:
an anode;
a cathode;
a light-emitting layer between the anode and the cathode; and
an intervening layer between the light-emitting layer and the cathode, wherein
the intervening layer is formed by a method involving:
synthesizing a first solution containing at least one nanoparticle made of a first material;
synthesizing a second solution prepared by adding, to the first solution, a second material that differs from the first material;
forming a second material portion made of the second material on at least a part of a surface of the at least one nanoparticle by subjecting the second solution to sonication; and
applying the second solution containing at least one of the at least one nanoparticle having the second material portion formed thereon.

4. The light-emitting element according to claim 1, wherein the second material has a lower electron mobility than the first material.

5. The light-emitting element according to claim 1, wherein the second material has a lower electron affinity than the first material.

6. The light-emitting element according to claim 3, wherein
the first material contains magnesium zinc oxide, and
the second material contains a metal oxide.

7. The light-emitting element according to claim 6, wherein the second material contains magnesium oxide.

8. The light-emitting element according to claim 1, wherein the light-emitting layer contains a light-emitting material in which cadmium atoms account for less than or equal to 0.01 wt % of all atoms.

9. The light-emitting element according to claim 1, further comprising a hole transport layer containing an inorganic material between the anode and the light-emitting layer.

10. The light-emitting element according to claim 1, further comprising:
a hole transport layer provided between the anode and the light-emitting layer and containing an organic material; and
a hole injection layer provided between the anode and the hole transport layer and containing an inorganic material.

11. The light-emitting element according to claim 1, wherein the second material portion covers greater than or equal to 10% of an outer circumference of the at least one nanoparticle in a cross-section of the at least one nanoparticle.

12. The light-emitting element according to claim 1, wherein the second material portion is insularly disposed on an outer circumference of the at least one nanoparticle in a cross-section of the at least one nanoparticle.

13. The light-emitting element according to claim 12, wherein the second material portion covers less than or equal to 90% of the outer circumference of the at least one nanoparticle in a cross-section of the at least one nanoparticle.

14. A display device comprising:
a substrate; and
a red light-emitting element, a green light-emitting element, and a blue light-emitting element on the substrate, wherein
at least one of the red light-emitting element, the green light-emitting element, and the blue light-emitting element is the light-emitting element according to claim 1.

15. The display device according to claim 14, wherein
at least two light-emitting elements in the red light-emitting element, the green light-emitting element, and the blue light-emitting element are the light-emitting elements according to claim 1, and
where of two light-emitting elements in the at least two light-emitting elements, a light-emitting element that exhibits a shorter emission wavelength is a short-wavelength element, and another light-emitting element that exhibits a longer emission wavelength is a long-wavelength element, a ratio of a cross-sectional area of the second material to a cross-sectional area of the first material in a cross-section of the intervening layer is smaller in the long-wavelength element than in the short-wavelength element.

16. A display device comprising:
a substrate; and
a red light-emitting element, a green light-emitting element, and a blue light-emitting element on the substrate, wherein
at least one of the red light-emitting element, the green light-emitting element, and the blue light-emitting element is the light-emitting element according to claim 2,
at least two light-emitting elements in the red light-emitting element, the green light-emitting element, and the blue light-emitting element are the light-emitting elements according to claim 2, and
where of two light-emitting elements in the at least two light-emitting elements, a light-emitting element that exhibits a shorter emission wavelength is a short-wavelength element, and another light-emitting element that exhibits a longer emission wavelength is a long-wavelength element, a ratio of a cross-sectional area of the second material to a cross-sectional area of the first material in a cross-section of the intervening layer is smaller in the long-wavelength element than in the short-wavelength element.

17. A display device comprising:
a substrate; and
a red light-emitting element, a green light-emitting element, and a blue light-emitting element on the substrate, wherein
at least one of the red light-emitting element, the green light-emitting element, and the blue light-emitting element is the light-emitting element according to claim 3,
at least two light-emitting elements in the red light-emitting element, the green light-emitting element, and the blue light-emitting element are the light-emitting elements according to claim 3, and
where of two light-emitting elements in the at least two light-emitting elements, a light-emitting element that exhibits a shorter emission wavelength is a short-wavelength element, and another light-emitting element that exhibits a longer emission wavelength is a long-wavelength element, a ratio of a cross-sectional area of the second material to a cross-sectional area of the first material in a cross-section of the intervening layer is smaller in the long-wavelength element than in the short-wavelength element.
